(19) United States
(12) Patent Application Publication
(10) Pub. No.: US 2009/0014830 A1
(43) Pub. Date: Jan. 15, 2009

(54) METHOD OF MANUFACTURING SEMICONDUCTOR DEVICE

(76) Inventors: Min-Hyung Lee, Cheongju-si (KR); Oh-Jin Jung, Bucheon-si (KR)

Correspondence Address: SHERR & VAUGHN, PLLC, 620 HERNDON PARKWAY, SUITE 200, HERNDON, VA, 20170, US

(21) Appl. No.: 12/168,116

(22) Filed: Jul. 5, 2008

(30) Foreign Application Priority Data
Jul. 9, 2007 (KR) 10-2007-0068630

(51) Int. Cl. H01L 29/00; H01L 21/02

(52) U.S. Cl. 257/531; 438/381; 257/E29.001; 257/E21.022

(57) ABSTRACT

A method of manufacturing a semiconductor device including at least one of the following steps: Forming an insulating film having at least one trench on and/or over a semiconductor substrate. Forming a metal film on and/or over a surface of an insulating film, including inside the trench. Forming a metal seed layer on and/or over the metal film inside the trench. Forming a metal plating layer on and/or over the metal seed layer to fill the trench.

The present application claims priority under 35 U.S.C. 119 to Korean Patent Application No. 10-2007-0068630 (filed on Jul. 9, 2007), which is hereby incorporated by reference in its entirety.

### BACKGROUND

Embodiments relate to a method of manufacturing a semiconductor device. In embodiments, a method of manufacturing a semiconductor device may improve manufacturing efficiency of a semiconductor device (e.g. an inductor as a passive device).

Low-priced aluminum (Al) may be used as a material for semiconductor wiring. However, aluminum may have limitations at relatively fast signal transmission speeds. Copper (Cu) may be suitable for achieving relatively fast signal transmission speeds. Copper (Cu) has not only a relatively specific resistance value, but also a relatively high Electro-Migration (EM) resistance, compared to aluminum (Al). A relatively low specific resistance value of copper (Cu) may be a factor that enables relatively fast signal transmission. A relatively high Electro-Migration (EM) resistance may be an important characteristic for stability and/or durability of a device. Copper (Cu), which has a relatively high Electro-Migration (EM) resistance compared to aluminum (Al), may have characteristics superior to aluminum (Al) and may therefore be used as a wiring material.

Copper (Cu) may be difficult to etch by dry etching. Accordingly, it may be practical to use a damascene process when working with copper (Cu). A damascene process is a process of forming metal wirings by depositing copper (Cu) on a patterned wafer (e.g. by electroplating) and removing unnecessary depositions (e.g. by a Chemical Mechanical Polishing (CMP) process).

In embodiments, high-speed operating and/or high-integration semiconductor devices (e.g. RFCMOS, Bipolar/SiGe, BiCMOS, and/or other similar devices) may include an inductor as a passive device, which may be formed using a damascene process.

FIGS. 1A to 1D are process sectional views illustrating methods of forming inductor wirings in a semiconductor device. As illustrated in FIG. 1A, insulating film 20 may be formed on and/or over semiconductor substrate 10. Insulating film 20 may have trenches 22 in which inductor metal lines will be formed. Insulating film 20 may have a thickness of 3 μm or more. Trenches 22 may be formed by etching insulating film 20 using a photoresist pattern formed on and/or over insulating film 20.

As illustrated in FIG. 1B, anti-diffusion film 30 may be formed on and/or over a surface of insulating film 20. Anti-diffusion film 30 may be formed in trenches 22. As illustrated in FIG. 1C, metal layer 18 is may be formed on and/or over anti-diffusion film 30 (e.g. using electroplating), such that trenches 22 are filled with metal. Copper (Cu) may be used as a material of metal layer 18.

As illustrated in FIG. 1D, metal layer 18 may be planarized (e.g. by Chemical Mechanical Polishing (CMP)). A planarization process may remove a portion of anti-diffusion film 30 that was formed on and/or over a top surface of insulating film 20. In this case, the Metal layer 18 may be removed together with a portion of anti-diffusion film 30 that was above insulating film 20 at the level of trenches 22. With planarization, metal lines 18a may be formed on and/or over substrate 10.

In relatively highly-integrated semiconductor devices, copper (Cu) may be used as a material of an inductor (e.g. metal lines 18a). Copper (Cu) implementation may include a damascene process. When a damascene process is implemented using copper (Cu) as an inductor material, metal layer 18 (e.g. having a thickness between 3 μm and 10 μm) formed on and/or over anti-diffusion film 30 inside trenches 22 may result in irregular stepped portions (illustrated in FIG. 1C). Metal layer 18 may be etched by a planarization process (e.g. Chemical Mechanical Polishing (CMP) process). A polishing process may require substantial materials and may therefore consume a relatively large amount of materials that may contribute to manufacturing costs. A polishing process may be time consuming, which may have negative contributions to manufacturing efficiency.

### SUMMARY

Embodiments relate to a method of manufacturing a semiconductor device, which may minimize manufacturing costs and/or manufacturing time, which may maximize manufacturing efficiency of semiconductor devices.

In embodiments, a method of manufacturing a semiconductor device may include at least one of the following steps: Forming an insulating film having at least one trench on and/or over a semiconductor substrate. Forming a metal film on and/or over a surface of an insulating film, including inside the trench. Forming a metal seed layer on and/or over the metal film inside the trench. Forming a metal plating layer on and/or over the metal seed layer to fill the trench.

### DRAWINGS

FIGS. 1A to 1D illustrate process sectional views of methods of forming inductor wiring in a semiconductor device.

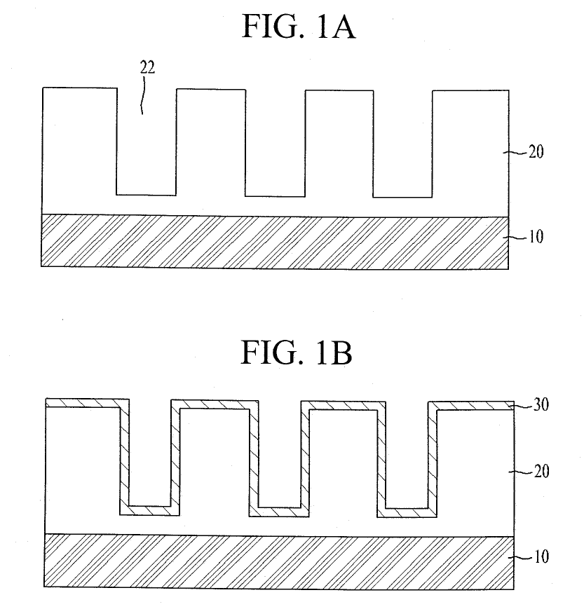

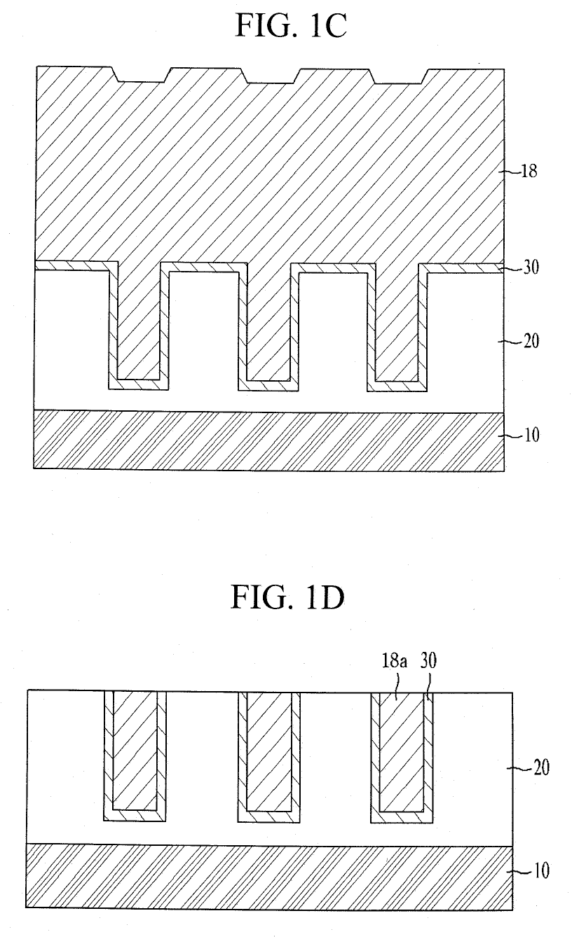

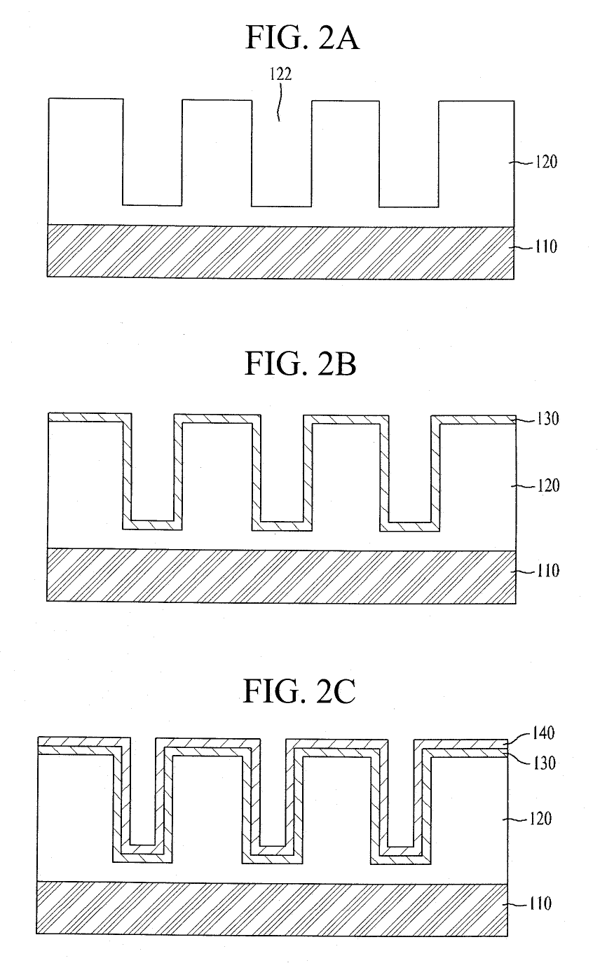

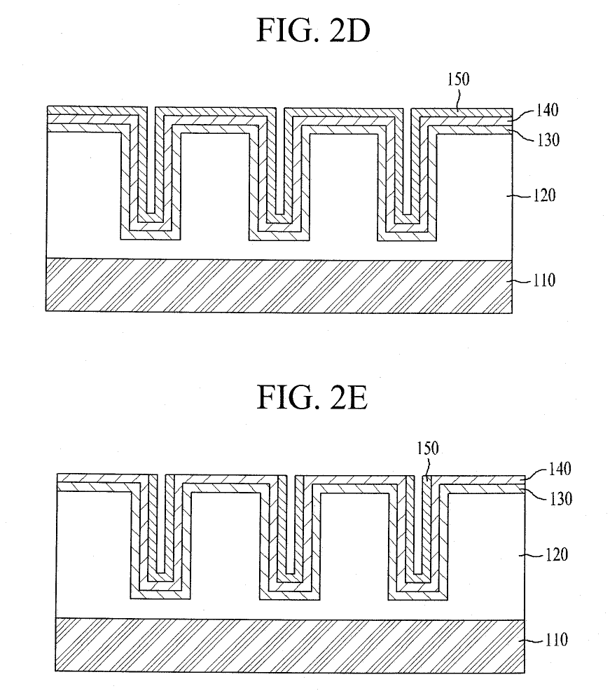

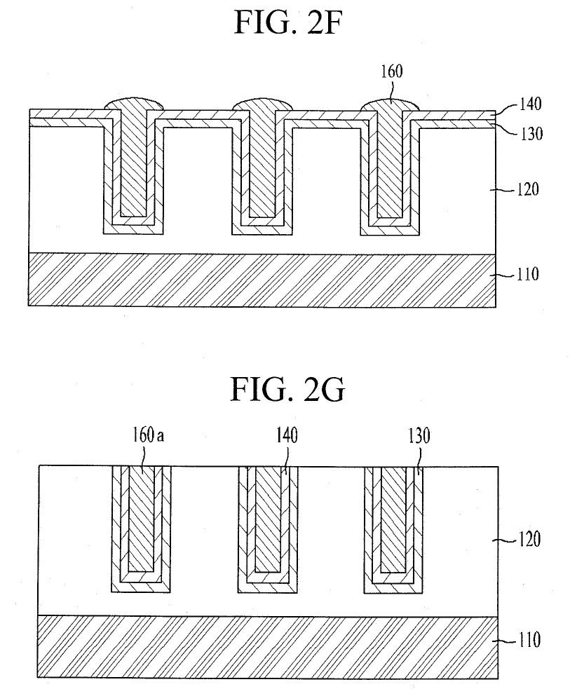

Example FIGS. 2A to 2G illustrate process sectional views of methods of forming a semiconductor device wirings, in accordance with embodiments.

### DESCRIPTION

Embodiments relate to a method of manufacturing an inductor in a semiconductor device using a damascene process. Example FIGS. 2A to 2G illustrate process sectional views of methods of forming semiconductor device wirings, in accordance with embodiments.

As illustrated in example FIG. 2A, insulating film 120 may be formed on and/or over semiconductor substrate 110, in accordance with embodiments. Insulating film 120 may have trenches 122, in which inductor metal lines may be formed. In embodiments, after insulating film 120 is formed (e.g. having a thickness between approximately 3 μm and 10 μm), a photoresist pattern may be formed. Insulating film 120 may be etched using the photoresist pattern as an etching mask to form trenches 22, in which inductor metal lines may be formed. In embodiments, insulating film 120 may be formed by Chemical Vapor Deposition (CVD) of FSG, SiO2, SiN, SiON, and/or a similar material.

As illustrated in example FIG. 2B, anti-diffusion film 130 may be formed on and/or over a surface of insulating film 120, which may include inside trenches 122. Anti-diffusion film 130 may prevent metal filled in trenches 122 from diffusing into insulating film 120. In embodiments, anti-diffusion film 130 may be formed by at least one of Atomic Layer Deposition (ALD), Physical Vapor Deposition (PVD), Chemical Vapor Deposition (CVD), and/or similar process.

In embodiments, anti-diffusion film 130 may include at least one of Ta, TaN, Ti, TiN, TaSiN, TiSiN, W, WNx, and/or similar material. Anti-diffusion film 130 may be formed to a thickness between approximately 50 Å to 500 Å, in accordance with embodiments. In embodiments, anti-diffusion film 130 may have a multilayer configuration.

As illustrated in example FIG. 2C, metal film 140 may be formed on and/or over anti-diffusion film 130, in accordance with embodiments. In embodiments, metal film 140 may have a thickness between approximately 50 Å and 500 Å. In embodiments, metal film 140 may include a metal (e.g. nickel (Ni), chromium (Cr), aluminum (Al), and/or similar material) on which an oxide film may be densely formed. In embodiments, anti-diffusion film 130, metal film 140 may be formed by at least one of Atomic Layer Deposition (ALD), Physical Vapor Deposition (PVD), Chemical Vapor Deposition (CVD), or a similar process. In embodiments, a natural oxide film may be densely formed on and/or over a surface of metal film 140.

Example FIG. 2D illustrates metal seed layer 150 (e.g. Cu) formed over metal film 140, in accordance with embodiments. In embodiments, metal seed layer 150 may have a thickness between approximately 100 Å and 1,000 Å. Prior to forming metal (e.g. Cu) seed layer 150, the surface of metal film 140 may be subjected to a plasma treatment, in accordance with embodiments. The plasma treatment may using at least one of Ar gas, H2 gas, and/or similar gas. The plasma treatment may enhance adhesion between the metal (e.g. Cu) seed layer 150 and metal film 140. In embodiments, a natural oxide film formed on and/or over metal film 140 may be removed by ejecting at least one of Ar gas, H2 gas, and/or a similar gas onto metal film 140. In embodiments, metal (e.g. Cu) seed layer 150 may be formed by at least one of Atomic layer Deposition (ALD), Physical Vapor Deposition (PVD), Chemical Vapor Deposition (CVD), and/or a similar process.

As illustrated in example FIG. 2E, a planarization process (e.g. a Chemical Mechanical Polishing (CMP) process) may be implemented to remove metal (e.g. Cu) seed layer 150 down to the level of metal film 140 on a top surface of trenches 122, in accordance with embodiments. For example, metal (e.g. Cu) seed layer 150 may only substantially remains in trenches 122.

As illustrated in example FIG. 2F, metal (e.g. Cu) plating layer 160 may be formed to fill trenches 122, in accordance with embodiments. In embodiments, no metal (e.g. Cu) plating may be implemented substantially outside of trenches 122, because metal (e.g. Cu) seed layer 150 is only formed inside trenches 122. Regions outside of trenches 122 may be covered with Ni, Cr, Al, and/or similar material on which a natural oxide film is densely formed, which may prevent metal plating from occurring. Metal (e.g. Cu) plating layer 160 may protrude out of trenches 122 (e.g. over a portion of metal (e.g. Cu) film 140, in accordance with embodiments.

As illustrated in example FIG. 2G, protruding portions of metal plating layer 160 be removed by a planarization process (e.g. Chemical Mechanical Polishing (CMP) process) to form metal lines 160a, in accordance with embodiments. In embodiments, portions of metal (Cu) plating layer 160 that do not fill trenches 122 may be removed. In embodiments, a planarization process may remove portions of metal film 140 and metal seed layer 150 that are not in trenches 122.

In embodiments, metal (e.g. Cu) lines 160a may be formed in trenches 122 such that metal (e.g. Cu) plating layer 160 is formed over insulating film 120 (e.g. having a thickness of approximately 1 μm or less.

In embodiments, consumption of copper (Cu) (or similar material) in metal plating layer 160 may be minimized, which may minimize manufacturing costs. In embodiments, since metal (Cu) plating layer 160 may be formed to be relatively thin, a Chemical Mechanical Polishing (CMP) process which may remove metal (Cu) plating layer 160a down to trenches 122 may be implemented with maximum efficiency (e.g. the process time minimized. In embodiments, copper (Cu) consumption may be minimized, which may minimize manufacturing costs. In embodiments, a metal (Cu) plating layer may be formed at a minimized thickness, which may minimize Chemical Mechanical Polishing (CMP) processing time, which may maximize manufacturing efficiency.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method comprising:
forming an insulating film over a semiconductor substrate;
forming at least one trench in the insulating film;
forming a metal film over the insulating film including inside said at least one trench;
forming a metal seed layer over the metal film including inside said at least one trench; and
forming a metal plating layer over the metal seed layer to fill said at least one trench.

2. The method of claim 1, comprising forming an anti-diffusion film over insulting film including inside said at least one trench.

3. The method of claim 2, wherein the anti-diffusion film has a thickness between approximately 50 Å and 500 Å.

4. The method of claim 2, wherein the anti-diffusion film comprises at least one of Ta, TaN, Ti, TiN, TaSiN, TiSiN, W, and WNx.

5. The method of claim 1, comprising performing a plasma treatment on a surface of the metal film prior to forming the metal seed layer.

6. The method of claim 5, wherein the plasma treatment comprises removing a natural oxide film formed over a surface of the metal film.

7. The method of claim 5, wherein the plasma treatment uses at least one of Ar gas and H2 gas.

8. The method of claim 1, comprising forming a metal line inside said at least one trench by polishing and removing the metal film, the metal seed layer, and the metal plating layer that is not inside said at least one trench to expose a portion of a surface of the insulating film.

9. The method of claim 1, wherein the insulating film is formed by chemical vapor deposition.

10. The method of claim 9, wherein the chemical vapor deposition using at least one of FSG, SiO2, SiN, and SiON.

11. The method of claim 9, wherein the insulating film has a thickness between approximately 3 μm and 10 μm.

12. The method of claim 1, wherein the metal film comprises at least one of nickel (Ni), chromium (Cr), and aluminum (Al).

13. The method of claim 1, wherein the metal film has a thickness between approximately 50 Å and 500 Å.

14. The method of claim 1, wherein the metal seed layer has a thickness between approximately 100 Å and 1,000 Å.

15. A apparatus comprising:
an insulating film formed over a semiconductor substrate;
at least one trench formed in the insulating film;
a metal film formed over the insulating film including inside said at least one trench; and
a metal plating layer formed over the metal film fill said at least one trench.

16. The apparatus of claim 15, wherein the metal plating layer is formed from a metal seed layer formed over the metal film.

17. The apparatus of claim 15, wherein at least one of the metal plating layer and the metal film are comprised in an inductor in a semiconductor device.

18. The apparatus of claim it, comprising an anti-diffusion film formed over insulting film including inside said at least one trench.

19. The apparatus of claim 15, wherein the metal plating layer comprises copper.

20. The apparatus of claim 15, wherein the metal film comprises at least one of nickel (Ni), chromium (Cr), and aluminum (Al).
